(19) United States
(12) Patent Application Publication
(10) Pub. No.: US 2020/0357635 A1
(43) Pub. Date: Nov. 12, 2020

(54) LARGE-SCALE SYNTHESIS OF 2D SEMICONDUCTORS BY EPITAXIAL PHASE CONVERSION

(71) Applicant: KING ABDULLAH UNIVERSITY OF SCIENCE AND TECHNOLOGY, Thuwal (SA)

(72) Inventors: Xiangming XU, Thuwal (SA); Husam Niman ALSHAREEF, Garland, TX (US)

(21) Appl. No.: 16/960,697

(22) PCT Filed: Dec. 12, 2018
(86) PCT No.: PCT/IB2018/059959

§ 371 Date: Jul. 8, 2020

Related U.S. Application Data
(60) Provisional application No. 62/698,460, filed on Jul. 16, 2018.
(60) Provisional application No. 62/620,021, filed on Jan. 22, 2018.

(51) Int. Cl. H01L 21/02; C30B 23/02; C30B 29/16; C30B 29/46; C23C 14/08; H01M 10/0525; H01M 4/48; C30B 31/08

(52) U.S. Cl. CPC H01L 21/02266; C30B 23/025; C30B 29/16; C30B 31/08; C23C 14/08; H01M 10/0525; H01M 4/48; C30B 29/46

(57) ABSTRACT

There is a method for forming an oxide or chalcogenide 2D semiconductor. The method includes a step of growing on a substrate, by a deposition method, a precursor epitaxy oxide or chalcogenide film; and a step of sulfurizing the precursor epitaxy oxide or chalcogenide film, by replacing the oxygen atoms with sulfur atoms, to obtain the oxide or chalcogenide 2D semiconductor. The oxide or chalcogenide 2D semiconductor has an epitaxy structure inherent from the precursor epitaxy oxide or chalcogenide film.

### CROSS-REFERENCE TO RELATED APPLICATIONS

This application claims priority to U.S. Provisional Patent Application No. 62/620,021, filed on Jan. 22, 2018, entitled “LARGE-SCALE SYNTHESIS OF 2D SEMICONDUCTORS BY EPITAXIAL PHASE CONVERSION PROCESS,” and U.S. Provisional Patent Application No. 62/698,460, filed on Jul. 16, 2018, entitled “LARGE-SCALE SYNTHESIS OF 2D SEMICONDUCTORS BY EPITAXIAL PHASE CONVERSION,” the disclosure of which is incorporated herein by reference in its entirety.

### BACKGROUND

### Technical Field

Embodiments of the subject matter disclosed herein generally relate to fabricating large-scale oxide or chalcogenides films, and more specifically, to large-scale MoS₂ films that are grown through a novel epitaxial phase conversion process, involving the preparation of high-quality epitaxial MoO₂ films, which are then converted, by sulfurization, to epitaxial MoS₂ films.

### Discussion of the Background

Recently, the generation of two-dimensional (2D) molybdenum disulfide (MoS₂) has attracted significant attention because of its unique electrical properties that can be tuned by controlling a thickness of the film. Many reports exist on 2-dimensional (2D) MoS₂ for various applications such as thin film transistors, soft electronics, valley electronics, photovoltaics, photodetectors, van der Waals heterostructures, and chemical or bio-sensors.

In the meantime, a variety of preparation methods have been developed for growing MoS₂ flakes and films with different thicknesses in order to meet the demands of these applications. For example, MoS₂ flakes prepared with mechanical and chemical exfoliation methods show excellent device properties because they contain fewer defects and grain boundaries, but are limited in scalability. Chemical vapor deposition (CVD) method is a viable way to grow both flakes and large-area films, but the variation of the number of 2D layers in the large-area CVD films poses a challenge to their practical implementation. Fortunately, metalorganic CVD (MOCVD) and CVD with seed layer coating on substrates were developed to prepare uniform MoS₂ films on wafer scale with excellent properties. However, this wafer-scale uniformity is only feasible for preparing monolayer MoS₂ films.

Currently, there is no viable method for depositing high-quality few-layer MoS₂ films (i.e., between 5 and 10 layers) on a large scale. Such films are reported to be advantageous in some aspects, including the possibility of higher mobility (see, for example, Zheng, J. et al. High-Mobility Multilayered MoS₂ Flakes with Low Contact Resistance Grown by Chemical Vapor Deposition, Adv. Mater. 29, 1604540 (2017)), feasibility of p-type doping through plasma (see, Nipane, A., Karmakar, D., Kaushik, N., Karande, S. & Lodha, S., Few-Layer MoS₂ p-Type Devices Enabled by Selective Doping Using Low Energy Phosphorus Implantation, ACS Nano 10, 2128-2137 (2016)), and the ability to form Schottky diodes with a barrier height that can be adjusted by the number of MoS₂ layers (Kwon, J. et al., Thickness-dependent Schottky barrier height of MoS₂ field-effect transistors, Nanoscale 9, 6151-6157 (2017)).

Thus, there is a need to develop high-quality few-layer MoS₂ thin films over a large area. Some efforts have already been exerted to grow large-area, few-layer MoS₂ films by various processes. These processes include direct pulsed laser deposition (PLD) (see, Serna, M. I. et al., Large-Area Deposition of MoS₂ by Pulsed Laser Deposition with In Situ Thickness Control, ACS Nano 10, 6054-6061 (2016)), pulsed metalorganic CVD (PMOCVD), or two-step processes, in which sulfurization of various precursors (e.g., MoO₃ (see, Lin, Y. C. et al., Wafer-scale MoS₂ thin layers prepared by MoO₃ sulfurization, Nanoscale 4, 6637-6641 (2012), Mo, (NH₄)₂MoS₄, and polymer-precursor complex thin films) is carried out. However, literature reports on few-layer MoS₂ films made with these methods show much poorer quality compared with flakes grown by CVD or exfoliation methods.

Therefore, there is a need for a new method for growing few-layer MoS₂ films that are not being affected by the above discussed shortcomings.

### SUMMARY

According to an embodiment, there is a method for forming an oxide or chalcogenide 2D semiconductor. The method includes a step of growing on a substrate, by a deposition method, a precursor epitaxy oxide or chalcogenide film, and a step of sulfurizing the precursor epitaxy oxide or chalcogenide film, by replacing the oxygen atoms with sulfur atoms, to obtain the oxide or chalcogenide 2D semiconductor. The oxide or chalcogenide 2D semiconductor has an epitaxy structure inherent from the precursor epitaxy oxide or chalcogenide film.

According to another embodiment, there is a MoS₂ electrode that includes a substrate and a single crystal MoS₂ film formed directly on the substrate. The single crystal MoS₂ film is formed by pulsed laser deposition (PLD), from a precursor single crystal MoO₂ film, and the precursor single crystal MoO₂ film is sulfurized to replace the oxygen atoms with sulfur atoms to obtain the MoS₂ film.

According to still another embodiment, there is a thin film transistor that includes a substrate, a single crystal MoS₂ film formed on the substrate, a drain electrode and a source electrode formed on the substrate and sandwiching the single crystal MoS₂ electrode, a dielectric layer formed over the drain electrode, the source electrode, and the single crystal MoS₂ electrode, and a gate electrode formed over the dielectric layer. The single crystal MoS₂ electrode is formed from a precursor single crystal MoO₂ film by pulsed laser deposition (PLD), and the precursor single crystal MoO₂ film is sulfurized to replace the oxygen atoms with sulfur atoms.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flowchart of a method for forming an epitaxial MoS₂ 2D film from a single crystal MoO₂ film;

FIG. 2 illustrates a pulse laser deposition system for fabricating ultrathin epitaxy MoO₂ film with atomic flat surface.

FIG. 3 is a flowchart of a method for depositing an epitaxial MoO₂ film;

FIG. 4 is a flowchart of a method for converting the single crystal MoO₂ film into the epitaxial MoS₂ 2D film;

FIG. 5 is a schematic of a tube furnace used for sulfurization;

FIGS. 6A and 6B are θ-2θ and Phi X-ray diffraction patterns of epitaxial MoO₂ films;

FIGS. 7A and 7B are θ-2θ and Phi X-ray diffraction patterns of epitaxial MoS₂ films should be as follows;

FIG. 8 illustrates the root mean square (RMS) roughness change for precursor MoO₂ and final MoS₂ films for different thicknesses;

FIG. 9A is an optical image of an MoS₂ film showing locations of various testing points and FIG. 9B is the Raman spectra of those testing points;

FIG. 10 illustrates a top gate thin film transistor made with epitaxy MoS₂ films;

FIGS. 11A and 11B show various characteristics of the top gate thin film transistor; and

FIG. 12 illustrates the characteristics of the epitaxial MoS₂ film comparative to similar materials.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a MoS₂ 2D film that may be used in a TFT transistor. However, the embodiments discussed herein are not limited to MoS₂ materials (as discussed later) or TFT transistors, as oxide or chalcogenides 2D films may be used for other purposes or in other electronic or photonic devices and in other devices such as a lithium-ion battery.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, there is method for epitaxial two-dimensional (2D) molybdenum disulfide (MoS₂) grown over a large area using a novel epitaxial phase conversion process. In this method, an epitaxial film of metallic MoO₂ is firstly grown by pulsed laser deposition and subsequently converted to a few-layer continuous 2D MoS₂ film. The term “epitaxial” is understood in the following to mean “a single crystal.” The term “film” is understood to mean a “sheet” having a certain thickness. The term “a single crystal film” is understood to mean a sheet having a certain thickness and having a structure that includes a single crystal. The term “layer” is understood to be related to the MoS₂ material, in the sense that a film of MoS₂ has a layered structure. This layered structure is defined as a plane of molybdenum atoms being sandwiched by planes of sulfide ions. These three strata form a monolayer of MoS₂. Thus, a few-layer MoS₂ film means a sheet of a given thickness, having a structure that includes a single crystal, and the atoms forming the film are distributed in substantially parallel planes, where three planes of molybdenum atoms and sulfide ions form a layer. The same method may be applied to other oxides and chalcogenides, e.g., WO₃, Ga₂O₃, TiO₂, etc. to form sulfides, selenides, and even tellurides of the same transition metal. However, for simplicity, the following embodiments are discussed with regard to MoS₂ films.

In all previous methods, poor electrical switching properties were reported for thin film transistors (TFTs) using MoS₂ semiconductor converted from Mo-based precursors over a large area (which is called as two-step process). However, with this novel method, epitaxial MoS₂ films can be prepared using epitaxial MoO₂ precursor films, followed by sulfurization to replace oxygen with sulfur. The resulting MoS₂-based TFTs prepared using this process achieve a field effect mobility as high as 10 cm² V⁻¹ s⁻¹, which is up to six times higher than the best reported few-layer MoS₂ devices prepared with a two-step process. In addition, lower operation voltage (−8 to 15 V) and on current to off current ratio (Iₒₙ/I_{off}) around 10⁵ are achieved. To the best of the inventor's knowledge, this process is the first MoS₂ growth that focuses on the quality of the precursor film MoO₂ (i.e., obtaining epitaxial precursors), and offers one or more of the following advantages: (1) scalable few-layer 2D film fabrication, (2) feasibility of thickness control over large area, and/or (3) possibility of epitaxial 2D MoS₂ growth.

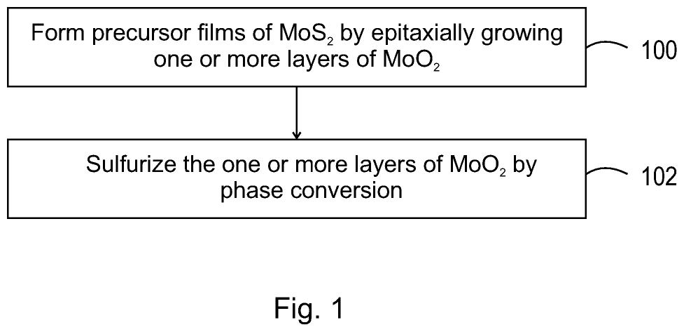

This method is now discussed in more detail with regard to FIG. 1. In step 100, one or more precursor single crystal (or epitaxial) MoS₂ films are formed. Note that by this process, the epitaxial MoO₂ with different thicknesses formed to be a single crystal instead of a poly-crystal as in the traditional methods. In this regard, the traditional processes use Mo-containing precursor films that are amorphous, which degrade the structure and performance of the resulting MoS₂ film. The precursor films in this embodiment are epitaxial (i.e., single crystal) over a large area. Further, the method used in this embodiment provides simultaneous (1) thickness control (one atomic layer at a time) and (2) growth over the large area. No other traditional process can generate MoS₂ films that are grain-boundary free, are grown over a large area, and show atomic thickness control (atomically flat surfaces).

In step 102, the precursor epitaxial MoO₂ films are sulfurized through a phase conversion process. For this process, the epitaxial MoO₂ film(s) is placed inside a tube furnace and sulfur powder may be used as the sulfurization source. The converted MoS₂ film was verified to also be epitaxial.

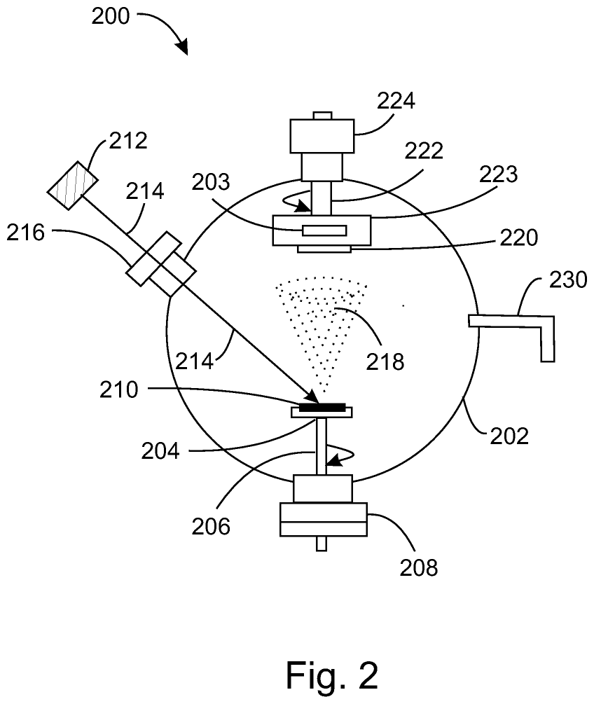

A system for performing step 100 is now discussed with regard to FIG. 2. In one application, a pulse laser deposition (PLD) technique is used to form the precursor MoS₂ film. Although the PLD method is discussed herein, one skilled in the art would understand that other methods may be used, for example, molecular beam epitaxy (MBE) or metalorganic vapor phase epitaxy (MOCVD). As illustrated in FIG. 2, a PLD system 200 includes a PLD chamber 202 that holds a target support 204. Target support 204 may be a plate that is attached with an axle 206 to a motor 208. The motor 208 may be formed outside the PLD chamber 202. Target support 204 holds the target material 210, which in this case is MoO₃. The motor 208 may rotate the target support 204 so that the target material 210 is rotated inside the PLD chamber 202.

A pulsed laser device 212, for example, a KrF₂ laser, may be used to generate a beam 214 that is directed through a port 216 inside the PLD chamber 202. The beam 214 interacts with the target material 210 and atoms or molecules of the precursor MoO₃ material are ablated. The ablated atoms and/or molecules 218 travel to a substrate 223, to form the MoO₂ layers 220. The substrate 223 may be, for example, a (0001) sapphire substrate. The substrate 223 is attached to a holder with an axle 222 to a motor 224. While motor 224 may be located outside the PLD chamber 202, the substrate 223 and the MoO₂ films 220 of are located inside the PLD chamber and both are located above the target material 210, so that the ablated atoms and/or molecules 218 travel vertically upwards toward the substrate 223. Thus, the ablated atoms and/or molecules 218 deposit, layer-by-layer as the MoO₂ film 220 onto the substrate 223. Substrate 223 may have a heater 203 for heating the substrate to a desired temperature (e.g., 400° C.). PLD chamber 202 may also have a port 230 through which oxygen or other gas may be inserted into the PLD chamber 202. In one application, the pulsed laser energy of the laser device 212 is about 210 mJ, the substrate 223's temperature is about 400° C., and the pressure of the oxygen gas is about 10 mtorr. It was observed that by using these parameters, it was possible to epitaxially grow the MoO₂ film, with not only a single crystalline structure and different thickness, but also with atomically smooth surface.

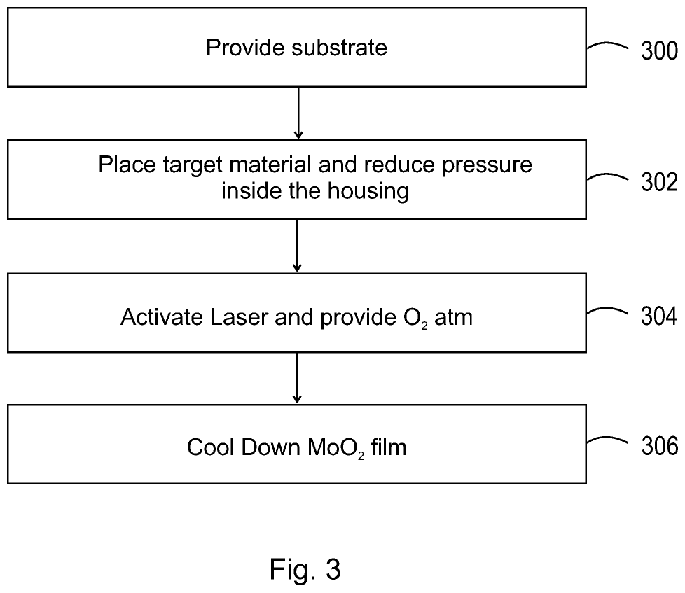

A specific implementation of step 100 is now discussed with regard to FIG. 3. In step 300, a (001) Al₂O₃ substrate 223 with, for example, an area of 10×10 mm and a thickness of 0.5 mm, was provided for the PLD system 200. Before applying the PLD process to this substrate, it was cleaned sequentially with acetone, IPA, and DI water, for 5 min in each solvent, combined with sonication. Then the substrate 223 was attached to the corresponding axle 222 (see FIG. 2).

In step 302, the target material 210 is placed inside the PLD's PLD chamber 202, on the target support 204, and the vacuum inside the PLD chamber is pumped down below 10⁻⁷ Torr. In this implementation, the target material 210 was MoO₃ having a purity of 99.9%. Other concentrations may be used. In step 304, the laser device 212 was activated to achieve the deposition of the MoO₂ layers 220 on the substrate 223. O₂ was used as the deposition atmosphere. During this step, the PLD chamber's pressure was kept at about 10 mTorr. The temperature of the substrate 223 during the deposition step was maintained at about 400° C. with the heater 203. The KrF₂ laser source 212, having a 248 nm wavelength, was used and set to a constant energy mode of about 210 mJ. The deposition rate of the MoO₂ film during step 304 was measured to be about 0.314 Å per shot. The substrate 223 was rotated during the deposition step with an angular speed between 20 and 40° per second, and more specifically, 36° per second. After deposition, in step 306, the MoO₂ layers 220 were cooled down to room temperature, naturally, before being taken out of the PLD chamber 202.

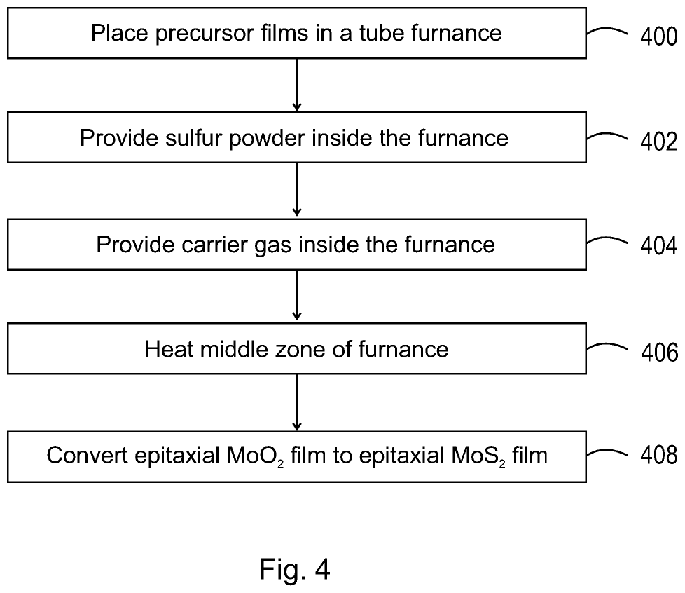

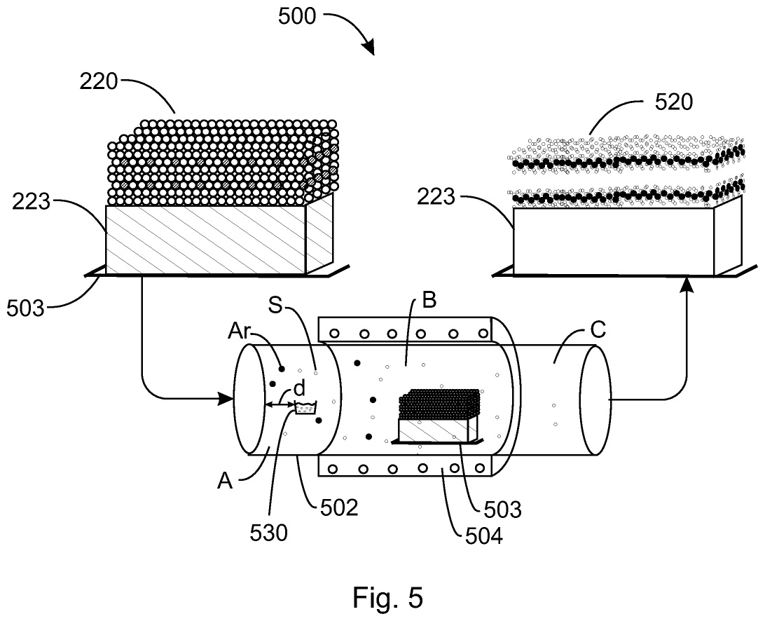

Next, a specific implementation of the sulfurization step 102 is discussed with regard to FIGS. 4 and 5. The precursor epitaxial MoO₂ films 220 were placed in step 400 in a cleaned quartz boat 503, which was loaded into the middle zone of a three-zone tube furnace 500, as shown in FIG. 5. The tube furnace 500 may have a body 502 that has an internal chamber. The internal chamber is split into three zones. The quartz boat 503 is placed inside the middle zone of the internal chamber. FIG. 5 shows the quartz boat 503 holding the substrate 223 and the MoO₂ films 220 from FIG. 2. Note that there is no sulfur in the substrate 223 or the films 220 when the quartz boat 503 is placed inside the tube furnace 500. Also note that a heater 504 is provided around the middle zone B of the tube furnace and the middle zone B is sandwiched between the first zone A and the last zone C.

In step 402, a sulfur powder 530 (e.g., from Fisher scientific, about 700 mg) is placed upstream of the quartz boat 503, at a given distance d, in the first zone A. In one embodiment, the distance d is about 27 cm. Argon is provided in step 404 as the carrier gas during sulfurization. In step 406, the heater 504 is activated for heating the middle zone B of the tube furnace 500. During this high-temperature process, the sulfur powder 530 evaporates and its vapor is transported by the carrier gas and incorporated into the epitaxial MoO₂ film 220. In step 408, the epitaxial MoO₂ film 220 is converted to an epitaxial MoS₂ film, by replacing the oxygen atoms with the sulfur atoms.

Before the sulfurization process, the Ar gas was flown through the quartz tube 502 with 100 sccm for at least 40 min, to completely remove the oxygen from the tube. The temperature rate increase in the middle zone B of the furnace was set at 20° C./min, starting from the room temperature, up to a desired maximum value (e.g., 700, 800, or 900° C.).

After reaching to the target value, the temperature inside the middle zone B of the furnace was held for 1 hr to complete the conversion of MoO₂ to MoS₂. Note that in one application, it is possible to convert each 0 atom to S. However, as would be understood by one skilled in the art, the conversion process does not have to convert each 0 atom. At the end of this step, the converted MoS₂ films 520 are cooled down to room temperature. The Ar flow was kept at 100 sccm throughout the process.

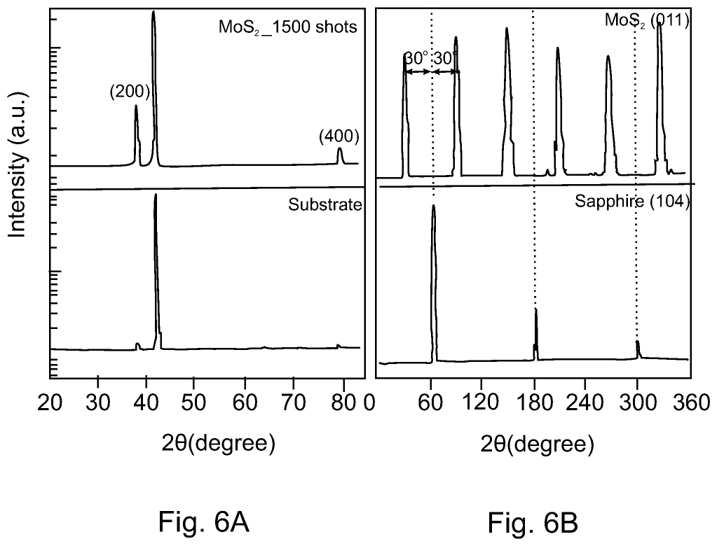

Some characteristics of the epitaxial growth of the MoO2 precursor films and the van der Waals MoS₂ converted films are now discussed. Molybdenum dioxide 520 (MoO₂, space group: P21/c(14)) was grown on the (001) surface of a single crystal Al₂O₃ substrate 223 (space group: R-3ch(167)). The MoO₂ film 220 was selected as the precursor film based on calculations showing that lattice mismatches below 2% can be achieved for the substrate and the MoO₂ film. The lattice parameters along the Al₂O₃ [120] and [100] directions are 0.5720 and 0.4762 nm, respectively, and both are in the (001) Al₂O₃ plane. In comparison, the lattice parameters along the MoO₂ [001] and [010] directions are 0.5628 and 0.4856 nm, respectively, both of which are in the MoO₂ (200) plane. Based on these values, the inventors have calculated the lattice mismatch to be −1.6% (tensile strain) for [001]MoO₂/[120]Al₂O₃, and 2.0% (compressive strain) for [010] MoO₂/[100] Al₂O₃. Because these strain values are negligible, it was decided to grow epitaxial (200) MoO₂ films on (001) Al₂O₃. In this respect, FIG. 6 shows the θ-2θ X-ray diffraction (XRD) pattern of epitaxial MoO₂ films deposited on (001) Al₂O₃ substrate using different numbers of PLD laser shots (100, 500, 1500). No diffraction peaks can be observed for films deposited with only 100 PLD shots, indicating that films deposited under these conditions are too thin. However, films deposited using 500 and 1500 shots clearly show only (200) MoO₂ (2θ=37.95°) and (400) (2θ=80.97°) diffraction peaks, indicating that these films are epitaxial. A phi (Φ) scan was performed to further investigate the epitaxial structure of the (200) MoO₂ films grown on (001) Al₂O₃ substrate, and the results confirm the epitaxial nature of the MoO₂ films. The Φ-scan shows the 60° inter-spaced peaks of (011) MoO₂ planes, indicating their six-fold symmetry, and the 120° inter-spaced peaks of (104) Al₂O₃ planes with three-fold symmetry. It is noted that the (011) MoO₂ peaks are offset by 30° relative to the (104) Al₂O₃ peaks, confirming the epitaxial nature of the MoO₂ film growth.

The θ-2θ XRD scan of both precursor MoO₂ film (1500 PLD shots) and final MoS₂ film (after sulfurization) on (001) Al₂O₃ substrate show two peaks. The peak at 16.65° can be assigned to (002) planes of 2H MoS₂, and the second peak at 41.80° can be assigned to (001) planes of the Al₂O₃ substrate. However, after sulfurization, the peak corresponding to (200) MoO₂ disappeared. This result indicates that the MoO₂ film has been completely converted to epitaxial MoS₂. A Φ scan was also performed to verify the epitaxial nature of the final MoS₂ film. It was observed that the (107) MoS₂ planes exhibit a six-fold symmetry, which is offset by 30° by the (104) Al₂O₃ peaks.

Raman spectroscopy was performed and successfully confirmed the formation of both the MoO₂ and MoS₂ structures. Actually, no MoO₂ Raman peaks were found in the final MoS₂ Raman spectra, further verifying the complete sulfurization of the precursor MoO₂ film. However, as previously discussed, the complete sulfurization of the precursor MoO₂ film is not a required condition.

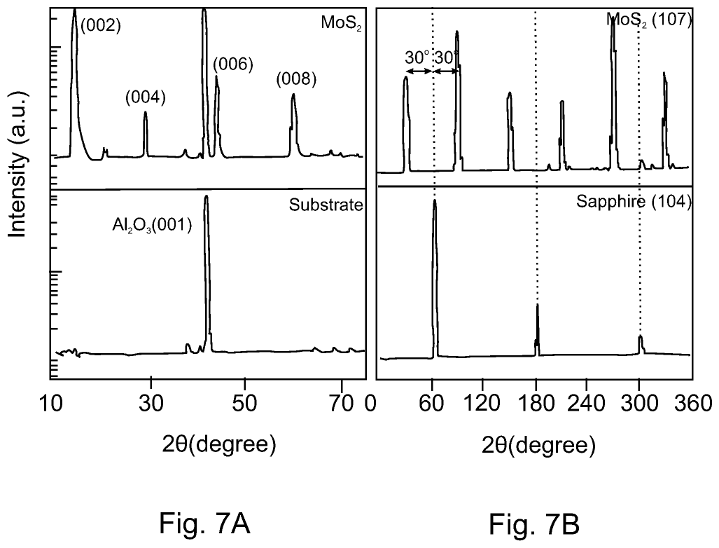

In one embodiment, to achieve high-quality MoS₂ films, the sulfurization temperature was selected using the 100 PLD shots for the MoO₂ film. Specifically, three different sulfurization temperatures (700, 800, 900° C.) were evaluated during the process of forming the epitaxial MoS₂ film. Raman, Photoluminescence (PL) and X-ray photoelectron (XPS) spectroscopy were performed on the MoS₂ films to evaluate their qualities. The Raman spectra in FIG. 7 show that two peak positions are always located at 384.6 and 409.6 cm⁻¹, regardless of the sulfurization temperature, and these peaks correspond to E¹_{2g} and A_{2g} modes of the MoS₂ films, respectively. However, a higher conversion temperature results in a higher intensity of both peaks.

These Raman spectra were further analyzed by Lorentz fitting. It was concluded that the full width at half maximum (FWHM) of these peaks becomes smaller as the sulfurization temperature increased, indicating that a better optical quality MoS₂ film is obtained at a higher temperature. In fact, when a sulfurization temperature of 900° C. was used, the FWHM of the E¹_{2g} peak was 3.74, which is close to the reported value (FWHM=3.5) for few-layer single crystalline MoS₂ flakes prepared by CVD. Higher PL peak intensity can also be observed in MoS₂ films obtained at a higher sulfurization temperature, further confirming the higher quality of MoS₂ at higher sulfurization temperature. XPS peaks at 232.9, 229.8 and 227, which correspond to Mo 3d_{3/2}, Mo 3d_{5/2} and S 2s, respectively, were observed. S 2p_{1/2} and S 2p_{3/2} peaks were observed at 163.8 and 162.6.

These peak positions are consistent with those reported for crystalline MoS₂ films. It is interesting to note that the different sulfurization temperatures that were used for obtaining the MoS₂ films do not cause any peak shift in the XPS spectrum, which indicates that the MoS₂ crystals can be obtained at all three temperatures. Further analysis was performed on XPS spectra by Lorentzian-Gaussian fitting to acquire the Mo/S ratio. It was determined that the Mo/S ratios of 1/1.88, 1/1.90 and 1/1.94 were obtained, corresponding to the sulfurization temperatures of 700, 800 and 900° C., respectively.

These results demonstrate that the most stoichiometric MoS₂ could be obtained using the 900° C. sulfurization process. The lowest MoS₂ surface roughness was also obtained at 900° C., as can be concluded from a root mean square (RMS) roughness analysis. The above analysis showed that a higher sulfurization temperature improves the 2D MoS₂ film's quality. However, it was also observed that there is a limit regarding the increase in temperature. By increasing the sulfurization temperature to more than 1000° C., resulted in the evaporation of the precursor MoO₂ film, which is undesirable. Thus, a sulfurization temperature in the range of 850 to 950° C. (referred herein to “about 900”) is believed to be preferable.

In order to investigate the sulfurization process in more detail, the surface morphology of the precursor MoO₂ films deposited using different PLD shots (40, 60, 80, 100, 120, 140, 160, 200, 300 shots) and the corresponding final MoS₂ films were studied by atomic force microscope (AFM). The typical AFM surface morphologies of MoO₂ films, having an RMS roughness of 0.147, 0.173 and 0.270 nm corresponding to films with 40, 100, and 300 shots, respectively, was studied. It was observed that an excellent surface smoothness of the precursor films was achieved (RMS <0.27 nm), although the RMS roughness increases slightly with the number of PLD shots.

For films having 40, 100, and 300 shots, the typical AFM surface morphologies of final MoS₂ films was observed. An RMS roughness of 2.554, 0.178 and 0.542 nm was observed for these MoS₂ films, which were converted from the MoO₂ films. Interestingly, the RMS roughness of the final 2D MoS₂ films changed significantly with the thickness (number of PLD laser shots) of MoO₂ films.

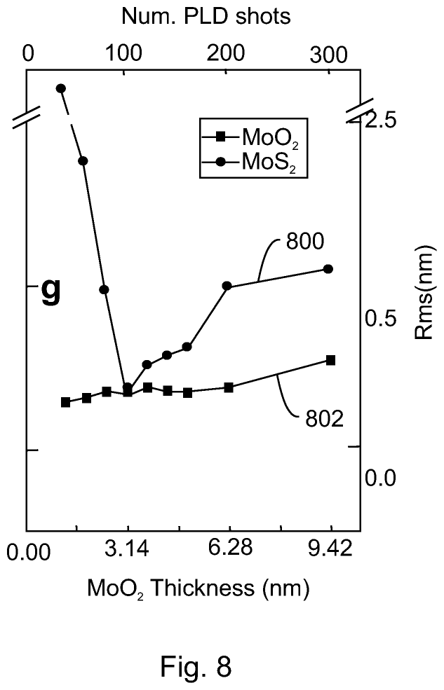

Precursor MoO₂ films deposited using 40 PLD shots resulted in isolated islands of MoS₂. As the number of PLD shots of the MoO₂ films increased, the islands began to coalesce, but continuous MoS₂ films were not formed until the number of MoO₂ PLD shots reached 100. The RMS roughness of the 2D MoS₂ films decreased before the formation of the continuous films, and then increased again after the formation of continuous 2D MoS₂ films. Essentially, the converted MoS₂ films showed higher roughness than the corresponding MoO₂ precursor. The only exception happened when the number of MoO₂ laser shots was 100 (3.15 nm thick MoO₂ film), where the continuous MoS₂ film has just formed. Thicknesses of the MoS₂ films obtained for different MoO₂ precursor thicknesses (PLD shots) was studied by AFM. Before the formation of the continuous MoS₂ film, the thickness changed nonlinearly with the number of MoO₂ laser shots, but once a continuous film has formed, it began to increase linearly with the number of laser shots, as shown by curve 800 in FIG. 8. However, the precursor MoO₂ film thickness always increased linearly with the number of laser shots, as shown by curve 802 in FIG. 8. Note that the thickness of the 2D MoS₂ film, converted from the MoO₂ film with 100 MoO₂ PLD shots, is about 3 nm, which corresponds to about 4-5 layers.

The sulfurization process of MoO₂ precursor film was discussed above with regard to FIGS. 4 and 5. MoO₂ epitaxial films with 100 shots were loaded into the tube furnace 500, and annealed in a mixture of Ar and S at 900° C. for 1 hr at atmospheric pressure, resulting in 2D epitaxial MoS₂ films 520 (see FIG. 5). A low-resolution (LR) TEM image of a 3.15 nm MoO₂ precursor film (100 PLD shots) was obtained and the film shows an atomically flat surface, consistent with the AFM data previously discussed. A high-resolution (HR) TEM image of the same epitaxial MoO₂ film was generated and it was observed that the (200) plane of MoO₂ is parallel to the (001) surface of the Al₂O₃ substrate. This means that excellent epitaxial growth of MoO₂ has been achieved, consistent with the conclusion from the XRD analysis previously discussed.

In comparison, the LR TEM image of the final MoS₂ film (obtained after 900° C. sulfurization) shown the thickness of the film to be 2.94 nm. The HR TEM image further shows the layer structure of the final film, with all layers perfectly parallel to the substrate surface, further confirming the van der Waals epitaxy. The Electron Energy Loss Spectroscopy (EELS) elemental mapping (S and O) of the MoO₂ and MoS₂ films were plotted together with the TEM images and by comparing the oxygen and sulfur elemental distribution, the complete sulfurization of the MoO₂ film was observed.

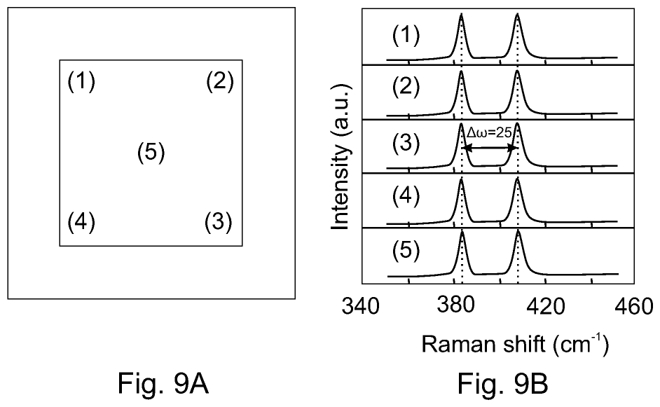

The uniformity of the epitaxial 2D MoS₂ films was also investigated. Optical images of the optimized MoS₂ film were obtained. To verify the uniformity of the MoS₂ films, five areas are chosen on the substrate (marked as 1), 2), 3), 4), 5) in FIG. 9A) and used for the Raman and AFM line scan characterizations. The Raman spectra at the marked points are shown in FIG. 9B. It can be seen that the positions of the MoS₂ Raman peaks are almost the same for all five spots with fixed peak separation of around 25 cm⁻¹. The AFM images and corresponding line profiles from these different areas further confirm the thickness uniformity of the five marked areas. The thickness of this MoS₂ film is around 3 nm, consistent with the TEM characterization. In order to further investigate the uniformity of the MoS₂ film, a randomly selected area (50×50 μm) was analyzed with the Raman mapping technique. The Raman mapping results of peak positions corresponding to E¹_{2g} and A_{2g} vibration modes and their peak difference Δω indicate that no crystal boundaries or obvious defects were detected, which is further proof of the high quality of this single crystal structure of epitaxial MoS₂ film. The distributions of the peak positions are very narrow: 383.8˜384.2 cm⁻¹ for E¹_{2g} peak, 408.8˜409.2 cm⁻¹ for the A_{2g} peak, and 24.9˜525.05 cm⁻¹ for the Δω.

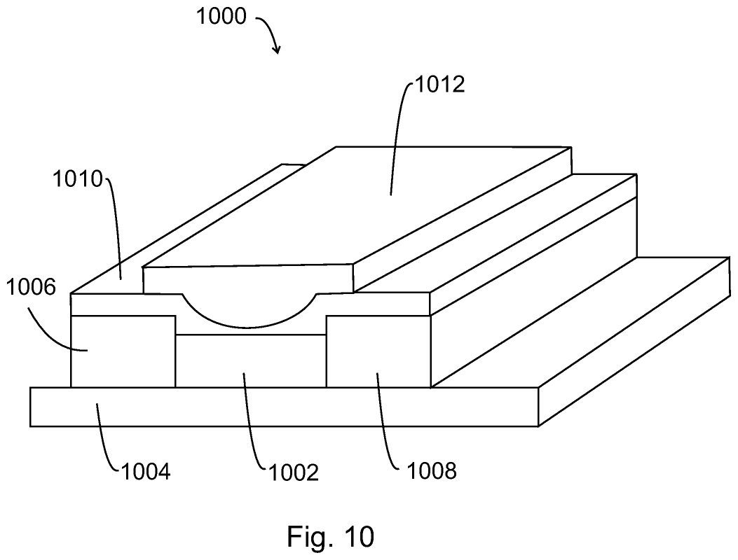

To check the electrical performance of the epitaxial 2D MoS₂ films (which may include between 5 and 10 layers according to the method discussed above), top-gate thin film transistors 1000 were fabricated as illustrated in FIG. 10. Epitaxial MoS₂ film 1002 was generated on a substrate 1004 (e.g., sapphire) as discussed above with regard to FIGS. 4 and 5. The epitaxial MoS₂ film 10d02 was patterned using, for example, photolithography followed by a dry etching process. Au/Ti source/drain electrodes 1006 and 1008 were grown on top of the MoS₂ film 1002 by e-beam evaporation (EBE), with lift-off process. HfO₂ dielectric 1010 was grown by atomic layer deposition (ALD) (e.g., 400 cycles, 62 nm) over the epitaxial MoS₂ film 1002 and electrodes 1006 and 1008. During the ALD process, the temperature was set as 160° C., and deionized water was used as the oxidization source with the pulse/purge time 0.015/8 s/s. Tetrakis(dimethylamido) hafnium (IV) precursor was used as Hf source, with pulse/purge time of 0.2/8 s/s. The top-gate electrode 1012 was grown by EBE and patterned by lift-off process. Once the device 1000 structure was prepared, it was annealed at 200° C. for 2 hrs in a tube furnace, for example, tube furnace 500. The annealing process was protected with Ar/H2 gas at a flow rate of 40/5 sccm, with an inner pressure kept at 1 torr. Before annealing, the tube 502 was purged 3 times with the Ar/H2 gas. The heating rate was set as 5° C./min. The furnace was naturally cooled to room temperature after the annealing process.

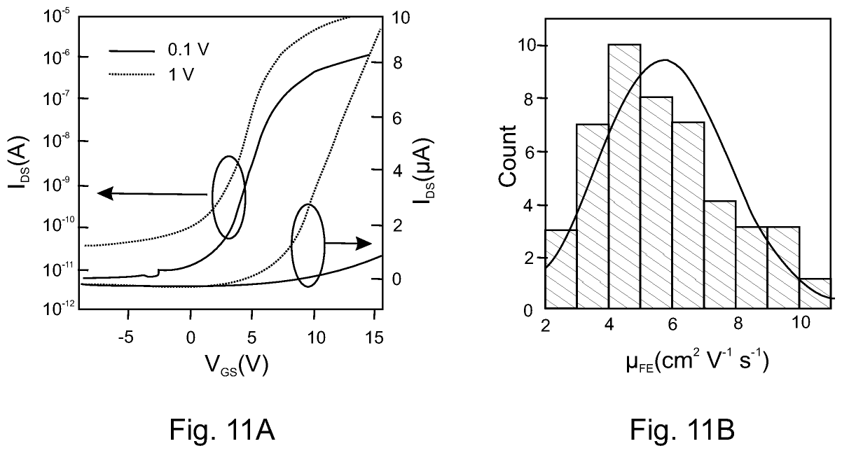

The structure of the top-gated MoS₂ TFT 1000 used HfO₂ as dielectric, and Au/Ti as source/drain (S/D) contacts and gate (G). Linear drain current (I_{DS}) levels (see FIG. 11A) were observed for the gate voltage ranging from −10 to 10 V (2 V per step), indicating the Ohmic contact between the MoS₂ channel 1002 and the source/drain 1006/1008, consistent with previous reports.

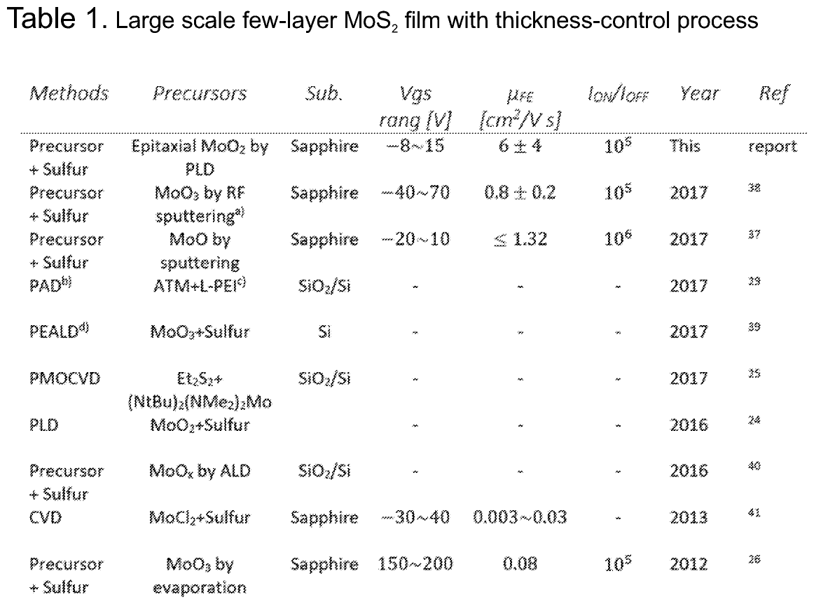

The capacitance per unit area is calculated to be 2.7×10-7 F/cm², and the dielectric constant of the HfO₂ is determined to be 18. The field-effect mobility (μFE) is calculated to be 8.5 cm² V⁻¹ s⁻¹. This μFE value is almost 6 times higher than the reported best few-layer MoS₂ device prepared from a two-step process. A detailed comparison to previous TFT devices on MoS₂ films obtained using the two-step process is shown in Table 1 in FIG. 12. The on-current to off-current (Iₒₙ/I_{off}) ratio is determined to be 2.75×10⁵, similar to the previous reports. The leakage current (I_{GS}) is less than 10⁻¹¹ A, which is two orders of magnitude lower than the I_{DS} used for mobility extraction, indicating that the effect of leakage current on mobility extraction is minimal. The threshold voltage (Vₜₕ) is determined to be 6.6 V, and the carrier density is calculated to be 1˜14×10¹² cm⁻² in the device operation range. Subthreshold swing (SS) is calculated (from the inverse of the maximum slope of the logarithmic transfer curve), to be 1.20 V dec⁻¹. The interface trap density (D_{IT}) is calculated as being 3.3×10¹³ cm⁻². The calculated D_{IT} is even higher than the carrier density, indicating that the interface between the MoS₂ film and the HfO₂ layer contains large amounts of carrier trapping centers. It is believed that if this interface can be improved, the TFT transistor could show even higher performance (such as higher μ_{FE}). The scalable increase in the I_{DS} with respect to the V_{DS} indicates the modulation of the drain current is by the field-effect, instead of the contact between S/D contact and the MoS₂ channel. FIG. 11B shows the distribution of μ_{FE} from 46 individual TFTs with different channel dimensions from the circuit shown in FIG. 10.

Table 1 in FIG. 12 shows a comparison of reported large-area few-layer MoS₂ films and their TFT performance. It can be seen that although the methods for preparing large-area few-layer MoS₂ films are frequently reported in the recent two years, the device's mobility of these MoS₂ TFT devices are all below 2 cm² V⁻¹ s⁻¹. In one embodiment, by using the MoS₂ films from the sulfurization of the epitaxial MoO₂ film, the TFTs show high field-effect mobility, which could even reach 10 cm² V⁻¹ s⁻¹, smaller gate voltage operation (˜8˜15 V), which means low power consumption during the device's operation, and competitive Iₒₙ/I_{off} ratios.

One or more embodiments discussed above achieve high-quality, continuous, few-layer epitaxial MoS₂ films, which were prepared by sulfurization of ultrathin epitaxial MoO₂ precursor film over a large area. Compared with all previous two-step processes, which normally perform sulfurization of precursor Mo based films, this is the first time the process focuses on optimizing the precursor film's quality before sulfurization.

The sulfurization process for achieving the best quality MoS₂ film was optimized so that the material characterization results show that the MoS₂ films grow epitaxially on the (001) Al₂O₃ substrate with excellent uniformity. Raman mapping depicted the uniformity and high optical quality with almost negligible defects and grain boundaries at the microscale. Raman and AFM measurements at several testing points further confirmed the thickness and uniformity at large area.

TFT devices fabricated using the optimized epitaxial few-layer MoS₂ films exhibited excellent electrical performance. Field-effect mobility values of 46 individual devices ranged from 4˜10 cm² V⁻¹ s⁻¹, which is up to 6 times higher than the best reported MoS₂ FET prepared from other two-step processes. These properties are even compatible with MoS₂ film from a CVD process. A switching ratio of about 10⁵ was obtained, which is similar to previous reports. The used gate voltage was between −8 and 15 V, indicating that a lower power consumption is possible with these devices.

Thus, one or more of the embodiments discussed above are capable of scalable fabrication, uniformity at the wafer scale, and the possibility for layer number control.

The disclosed embodiments provide a MoS₂ film made of a few layers and method for making the same in which the film includes a single crystal. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A method for forming an oxide or chalcogenide 2D semiconductor, the method comprising:
growing on a substrate, by a deposition method, a precursor epitaxy oxide or chalcogenide film; and
sulfurizing the precursor epitaxy oxide or chalcogenide film, by replacing the oxygen atoms with sulfur atoms, to obtain the oxide or chalcogenide 2D semiconductor,
wherein the oxide or chalcogenide 2D semiconductor has an epitaxy structure inherent from the precursor epitaxy oxide or chalcogenide film.

2. The method of claim 1, wherein the precursor epitaxy oxide or chalcogenide film is a precursor single crystal MoO₂ film, the oxide or chalcogenide 2D semiconductor is a MoS₂ semiconductor, and the deposition method is one of pulse laser deposition, metalorganic vapor phase epitaxy or molecular beam epitaxy.

3. The method of claim 2, further comprising:
providing the substrate inside a chamber of a pulse laser deposition (PLD) system;
placing a target material on a target support underneath the substrate with a certain distance inside the PLD chamber; and
irradiating with a laser beam the target material to ablate atoms of the target material,
wherein the ablated atoms travel to the substrate and form the precursor single crystal MoO₂ film.

4. The method of claim 3, wherein the target material is MoO₃.

5. The method of claim 3, wherein the substrate is located above the target support.

6. The method of claim 3, wherein the substrate and the target support rotate.

7. The method of claim 3, wherein the substrate rotates with an angular speed between 20 and 40° per second.

8. The method of claim 3, further comprising:
providing an O₂ atmosphere inside the PLD chamber.

9. The method of claim 8, further comprising:
cooling down the MoO₂ film.

10. The method of claim 3, further comprising:
activating the laser beam about 100 times to generate the precursor single crystal MoO₂ film.

11. The method of claim 3, wherein a thickness of the precursor single crystal MoO₂ film is about 3 nm.

12. The method of claim 3, further comprising:
placing the precursor single crystal MoO₂ film into a middle zone of a tube furnace having three different zones;
providing sulfur powder into a first zone of the tube furnace, upstream the middle zone;
supplying a carrier gas from the first zone towards the middle zone; and
heating the middle zone of the tube furnace to evaporate the sulfur.

13. The method of claim 12, wherein the sulfur is transported by the carrier gas from the first zone to the middle zone and the sulfur replaces the oxygen in the precursor single crystal MoO₂ film.

14. The method of claim 13, wherein the precursor single crystal MoO₂ film becomes a single crystal MoS₂ 2D film as a result of the replacement of oxygen atoms with sulfur atoms.

15. The method of claim 12, wherein the step of heating is performed to increase a temperature of the middle zone from room temperature to about 900° C.

16. The method of claim 15, wherein the step of heating is performed at a rate of about 20° C./min.

17. The method of claim 2, wherein the MoS₂ 2D semiconductor has between 5 and 10 layers.

18. A MoS₂ electrode comprising:
a substrate; and
a single crystal MoS₂ film formed directly on the substrate,
wherein the single crystal MoS₂ film is formed by pulsed laser deposition (PLD), from a precursor single crystal MoO₂ film, and the precursor single crystal MoO₂ film is sulfurized to replace the oxygen atoms with sulfur atoms to obtain the MoS₂ film.

19. The MoS₂ electrode of claim 18, wherein the MoS₂ electrode has between 5 and 10 layers.

20. A thin film transistor comprising:
a substrate;
a single crystal MoS₂ film formed on the substrate;
a drain electrode and a source electrode formed on the substrate and sandwiching the single crystal MoS₂ electrode;
a dielectric layer formed over the drain electrode, the source electrode, and the single crystal MoS₂ electrode; and
a gate electrode formed over the dielectric layer,
wherein the single crystal MoS₂ electrode is formed from a precursor single crystal MoO₂ film by pulsed laser deposition (PLD), and the precursor single crystal MoO₂ film is sulfurized to replace the oxygen atoms with sulfur atoms.

21. The thin film transistor of claim 19, wherein the MoS₂ electrode has between 5 and 10 layers.
